(19) United States
(12) Patent Application Publication
(10) Pub. No.: US 2013/0286705 A1
(43) Pub. Date: Oct. 31, 2013

(54) LOW POWER CONTENT ADDRESSABLE MEMORY HITLINE PRECHARGE AND SENSING CIRCUIT

(71) Applicants: David B. Grover, Eden Prairie, MN (US); Richard J. Stephani, St. Paul, MN (US); Christopher D. Browning, Inver Grove Heights, MN (US)

(72) Inventors: David B. Grover, Eden Prairie, MN (US); Richard J. Stephani, St. Paul, MN (US); Christopher D. Browning, Inver Grove Heights, MN (US)

(21) Appl. No.: 13/456,419

(22) Filed: Apr. 26, 2012

(51) Int. Cl. G11C 15/00; G11C 7/12

(52) U.S. Cl. 365/49.17; 365/203

(57) ABSTRACT

An apparatus and a method of operating the apparatus. The apparatus includes a driver circuit and a memory circuit. The driver circuit may be configured to precharge a hitline in response to a predetermined voltage level and a control signal and sense a result of a compare operation based upon a hitline signal on the hitline. The driver circuit generally precharges the hitline to a voltage level lower than the predetermined voltage level and senses the result of the compare operation using the full predetermined voltage level. The memory circuit may be configured to perform the compare operation using the hitline.

### FIELD OF THE INVENTION

The present invention relates to memory devices generally and, more particularly, to a method and/or apparatus for implementing a low power content addressable memory (CAM) hitline precharge and sensing circuit.

### BACKGROUND OF THE INVENTION

Conventional content addressable memories (CAMs) use a wide NOR structure. In the conventional architecture, a single positively-doped field effect transistor (PFET) device and a large number of CAM core cells with negatively-doped field effect transistor (NFET) pull-down devices are connected together by a hitline (or matchline). The hitline is also connected to an input of a sensing inverter. The PFET device precharges the hitline to a supply voltage (VDD) and is turned off. If there is a mismatch (or miss), one or more of the core pull-down NFET devices are turned on and the hitline discharges to a ground potential (VSS). If all the bits match (or hit) the hitline remains charged. The sensing inverter senses whether the bits on the hitline are a hit or miss and buffers the information to a next block of logic.

The conventional architecture is area efficient and fast. However, a disadvantage of the conventional architecture is the large dynamic power consumed. Conventional content addressable memories (CAMs) consume large amounts of power during compare operations. The power used during compare operations is more than the power used during read or write operations. In most CAM memories, a vast majority of the time is spent performing compare operations. One-third of the power used by the conventional CAM can be consumed in the precharging of the hitline alone. Thus, reducing overall power usage for compare operations can help reduce overall maximum power.

It would be desirable to implement a low power CAM hitline precharge and sensing circuit.

### SUMMARY OF THE INVENTION

Embodiments of the invention include a driver circuit and a memory circuit. The driver circuit may be configured to precharge a hitline in response to a predetermined voltage level and a control signal and sense a result of a compare operation based upon a hitline signal on the hitline. The driver circuit generally precharges the hitline to a voltage level lower than the predetermined voltage level and senses the result of the compare operation using the full predetermined voltage level. The memory circuit may be configured to perform the compare operation using the hitline.

### BRIEF DESCRIPTION OF THE DRAWINGS

Embodiments of the invention will be apparent from the following detailed description and the appended claims and drawings in which:

FIG. 1 is a block diagram illustrating a memory including a hitline precharge and sensing circuit in accordance with an example embodiment of the present invention;

FIG. 2 is a circuit diagram illustrating an example hitline precharge and sensing circuit implemented in accordance with an embodiment of the present invention;

FIG. 3 is a circuit diagram illustrating another example of a hitline precharge and sensing circuit implemented accordance with an embodiment of the present invention; and

FIG. 4 is a block diagram illustrating an example of a CAM memory core comprising a plurality of hitlines and hitline precharge and sensing circuits implemented in accordance with an embodiment of the present invention.

### DETAILED DESCRIPTION OF THE INVENTION

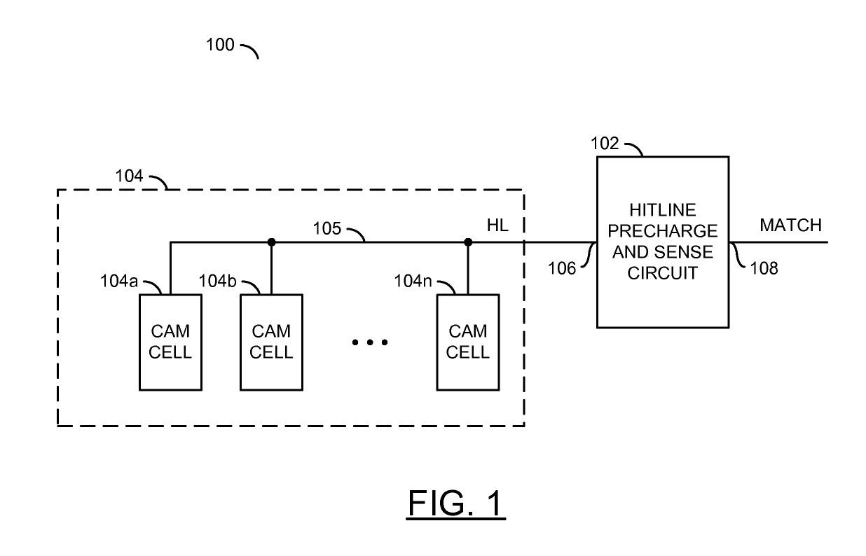

Referring to FIG. 1, a diagram of a circuit 100 is shown illustrating a content addressable memory (CAM) with a hitline precharge and sensing circuit in accordance with an embodiment of the invention. The circuit 100 may comprise a block (or circuit) 102 and a block (or circuit) 104. The block 102 may implement a hitline precharge and sensing circuit in accordance with an embodiment of the present invention. The block 104 may implement a portion of a memory core. The block 104 may comprise a number of NOR-based content addressable memory (CAM) bit cells 104a-104n. The CAM bit cells 104a-104n may be connected to a hitline 105. A complete memory core of the circuit 100 may comprise a plurality of blocks 104 and associated hitlines, where each of the hitlines may be connected to a respective one of a plurality of blocks 102.

The circuit 100 generally has three main operations—read, write, and compare. A write operation is normally used to load data into the block 104. A read operation may allow a user to verify the contents of each address of the block 104. The compare operation may be used to compare data-in bits to the contents stored in the block 104. The compare operation may provide a user with an output identifying which, if any, of the entries in the block 104 match the data-in bits. Determining whether any of the entries in the block 104 match the data-in bits generally involves pre-charging the hitline 105 to a pre-charged state and sensing a change in the pre-charged state in response to the compare operation. The block 102 generally handles the pre-charging and sensing operations.

The block 102 may have an input 106 that may receive a signal (e.g., HL) from the hitline 105 and an output 108 that may present a signal (e.g., MATCH). The signal HL may be referred to as a hitline signal. The signal MATCH may be configured to indicate whether a compare operation with the number of content addressable memory cells 104a-104n has resulted in a hit or a miss. Each of the content addressable memory cells 104a-104n may be connected to the hitline 105. In one example, the circuit 100 may comprise a plurality of the blocks 102 and 104 coupled accordingly.

Conventional NOR-based CAMs precharge hitlines to full rail (e.g., VDD). The block 102 generally precharges the hitline 105 to a voltage level slightly higher than one-half the supply voltage of the circuit 102 (e.g., ˜VDD/2 for the case where the supply voltage is VDD). The block 102 reduces the dynamic power consumed by a CAM and provides faster sensing of a miss. By reducing the dynamic power, the block 102 generally provides a significant total dynamic power savings for the entire memory. By sensing a miss faster, the block 102 increases the frequency at which the entire memory operates. For example, when a single bit miss occurs, only one bit cell is pulling down the entire hitline 105. The hitline 105 is generally highly capacitive. Because the hitline 105 is highly capacitive, the slew rate of the signal HL on a miss may be very slow. Since the starting point of signal HL in a memory implemented in accordance with an embodiment of the invention is lower (e.g., ˜VDD/2), the amount of time taken to trigger a miss is generally much shorter, therefore speeding up the entire circuit and memory.

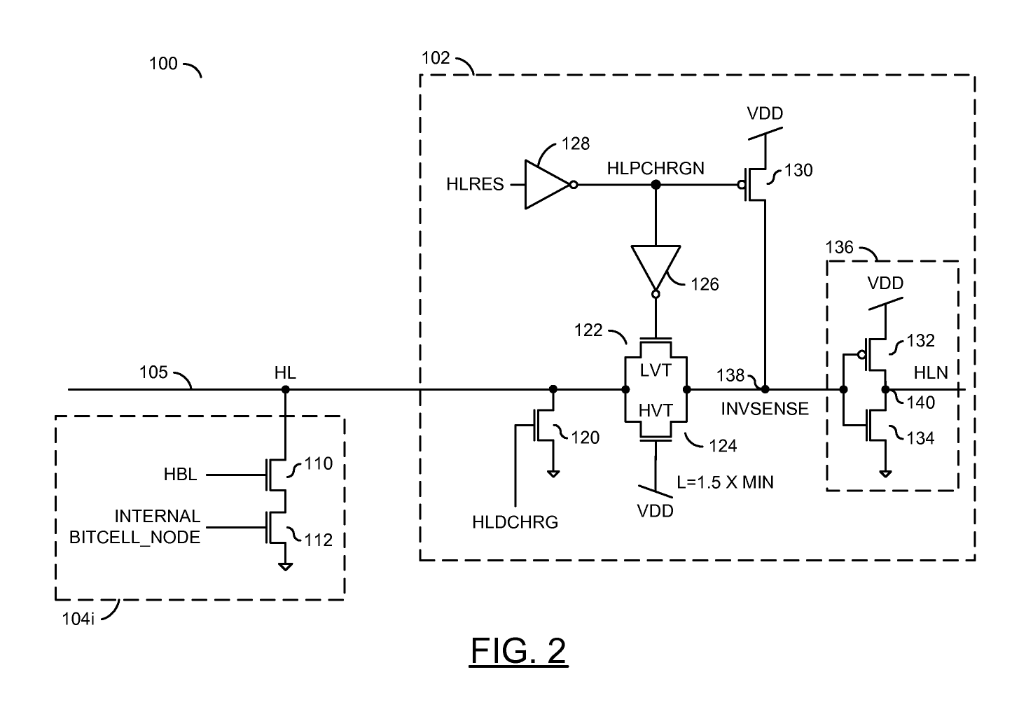

Referring to FIG. 2, a more detailed diagram of the circuit 100 is shown illustrating an example implementation of the hitline precharge and sensing circuit in accordance with an embodiment of the invention. A typical CAM bit cell 104i illustrated in FIG. 2, corresponding to CAM bit cells 104a-104n in FIG. 1, may comprise a transistor 110, a transistor 112 and a memory bitcell (not shown). The transistors 110 and 112 may be implemented as NFETs and the memory bitcell may be implemented as a six transistor (6T) static random access memory (SRAM) cell (not shown). A drain of the transistor 110 is connected to the hitline 105. A gate of the transistor 110 receives a signal (e.g., HBL). The signal HBL may be implemented as a hit bitline signal. A source of the transistor 110 may be connected to a drain of the transistor 112. A gate of the transistor 112 may be connected to an internal node of the memory bitcell. A source of the transistor 112 may be connected to a power supply ground potential.

In one example, the block 102 may comprise a transistor 120, a transistor 122, a transistor 124, a logic gate 126, a logic gate 128, a transistor 130, a transistor 132, and a transistor 134. The transistors 120, 122, 124, and 134 may be implemented as NFETs.

The transistors 130 and 132 may be implemented as PFETs. The logic gate 126 may be implemented, in one example, as an inverter. The logic gate 128 may be implemented, in one example, as an inverter. A source of the transistor 122 may be connected to a source of the transistor 124 and a drain of the transistor 122 may be connected to a drain of the transistor 124 to form a transmission or pass gate. The transistors 132 and 134 may be connected to form a complementary metal-oxide-semiconductor (CMOS) inverter 136.

In general, the transistors 122 and 124 are implemented such that the transistor 122 has a voltage threshold (e.g., LVT) that is lower than a voltage threshold (e.g., HVT) of the transistor 124 (e.g., LVT<HVT). In general, any technique available that provides the transistor 122 with a lower voltage threshold than the transistor 124 may be employed. In one example, the transistor 122 may be implemented using a device from a lower voltage threshold cell library and the transistor 124 may be implemented using a device from a higher voltage threshold cell library. For example, the transistors 122 and 124 may be implemented using processes that support multiple voltage thresholds (e.g., multi-VT). The multi-VT processes may have more than one VT adjustment processing step. In general, VT adjustment is done by ion implantation into a channel region of the transistor: few ions are implanted for a high-VT transistor, a bit more ions are implanted for a medium-VT transistor, and the most ions are implanted for a low-VT transistor. High-VT devices are generally part of a low leakage power library. High-VT devices are generally for low power use, but low critical timing. Medium-VT devices are generally part of a middle leakage power library. Medium-VT devices are typically for general purpose use. Low-VT devices are generally part of a big leakage power library. Low-VT devices are generally used for timing critical paths. In some alternative embodiments, the difference in voltage thresholds between the transistor 122 and the transistor 124 may be accomplished by implementing the transistors with different lengths. For example, the transistor 122 may be implemented having a first length (e.g., L) and the transistor 124 may be implemented having a second length (e.g., K*L, K>1). In still other embodiments, the difference in voltage thresholds between the transistor 122 and the transistor 124 may be accomplished by implementing the transistors with different bulk voltages, or a combination of the multi-VT devices, different lengths and different bulk voltages. In general, the voltage thresholds of the transistors other than the transistors 122 and 124 are not critical and, therefore, the other transistors may be implemented using any devices available.

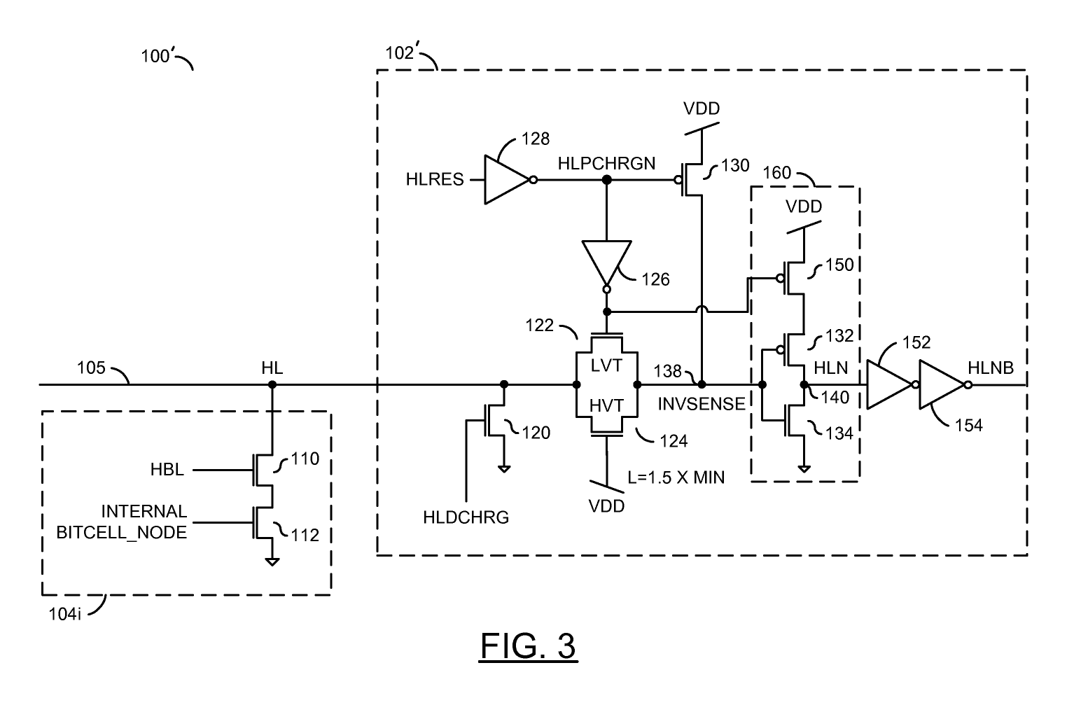

The hitline 105 is connected to a drain of the transistor 120 and the sources of the transistors 122 and 124. A gate of the transistor 120 receives a signal (e.g., HLDCHRG). A source of the transistor 120 is connected to the power supply ground potential. A gate of the transistor 122 is connected to an output of the logic gate 126. A gate of the transistor 124 is connected to the power supply voltage of the block 102 (e.g., VDD). A signal (e.g., HLRES) is presented to an input of the logic gate 128. An output of the logic gate 128 may present a signal (e.g., HLPCHRGN). The signal HLPCHRGN may be presented to an input of the logic gate 126 and a gate of the transistor 130. A source of the transistor 130 is connected to the power supply voltage of the block 102. A drain of the transistor 130, the drains of the transistors 122 and 124, a gate of the transistor 132 and a gate of the transistor 134 are connected, forming a sensing node 138 at which a signal (e.g., INVSENSE) may be presented (or developed). The signal INVSENSE generally represents a voltage level of the sensing node 138. A source of the transistor 132 is connected to the power supply voltage of the block 102. A source of the transistor 134 is connected to the power supply ground potential. A drain of the transistor 132 is connected to a drain of the transistor 134, forming a node 140 at which a signal (e.g., HLN) may be presented. The signal HLN, with at least one of the transistors 122 and 124 in a conductive state, is generally the complement of the signal HL. The signal HLN may be used as an output of the block 102. Alternatively, the signal HLN may be buffered prior to being used as an output (described below in connection with FIG. 3).

While an embodiment of the invention is illustrated and described as charging a hitline using a supply voltage, one skilled in the art would recognize that a predetermined voltage level other than the supply voltage but large enough to achieve the function of pre-charging the hitline, accounting for losses in transistors, could be used. Such an alternative voltage level could be less than the supply voltage.

The block 102 generally provides a sensing voltage differential. The block 102 is generally configured to allow the signal INVSENSE at the sensing node 138 to stay at the full supply voltage (e.g., VDD) when the hitline 105 is at about VDD/2.

Because the signal INVSENSE at the sensing node 138 remains at the full supply voltage, the voltage margin lost with a precharge of ˜VDD/2 is restored for the hit case. If the sense inverter 136 was connected to the hitline 105 directly and there was a hit, any noise on the hitline 105 might make the transistor 132 turn on and register a false miss. The architecture of the sensing circuit in accordance with an embodiment the invention generally makes the hit case as robust as if the hitline 105 were precharged to the full rail (e.g., VDD).

Both of the transistors 122 and 124 are used for precharge, while only the transistor 124 is used for sensing. The effective voltage threshold difference between the one device conducting and the two devices conducting generally creates a sense margin that ensures both a “1” and a “0” are sensed correctly. The transistors 122 and 124, when used together, have a lower effective device voltage threshold and, therefore, precharge the hitline 105 to a higher level than would be obtained using only the single device, transistor 124. During sensing, the single device, transistor 124, is used, which causes the switch level of the sense inverter 136 to be lower.

The precharging of the hitline 105 to ˜VDD/2 is generally performed as follows. The hitline 105 generally starts at the power supply ground potential (e.g., VSS=0V). When a compare operation is triggered the signal HLRES is pulsed high turning on the transistor 122 and the transistor 130. The signal INVSENSE goes to the full supply voltage (e.g., VDD) and the hitline signal HL starts charging HIGH. The hitline 105 can only charge to a maximum of the supply voltage of the block 102 minus the voltage threshold of the transistor 122 (e.g., VDD-LVT) because of the voltage drop across the transistor 122. The hitline signal HL does not generally get to the VDD-LVT level because of the high capacitance of the hitline 105 and a pulse duration of the signal HLRES being purposely kept short, thus reducing charging time. After the signal HLRES transitions LOW, the signal HBL in the typical bit cell 104i may switch HIGH, activating the compare portion of the operation.

The precharge happens as described above and when the signal HLRES is LOW the transistor 122 is OFF. The signal INVSENSE at the sensing node 138 is generally at the full supply voltage (e.g., VDD) and the hitline signal HL is generally at a voltage level of approximately one-half the supply voltage (e.g., ˜VDD/2). When there is a hit, the hitline signal HL remains at the voltage level of approximately VDD/2. The only remaining path between the hitline 105 and the sensing node 138 is the transistor 124. In order for the transistor 124 to fully conduct there needs to be a voltage difference between the source and drain of the transistor 124 that is greater than the particular threshold voltage (e.g., HVT) of the transistor 124. Therefore, when the difference between the voltage level of the signal INVSENSE at the sensing node 138 (e.g., V(INVSENSE)) and the voltage level of the hitline signal HL (e.g., V(HL)) is less than the threshold voltage of the transistor 124 (e.g., V(INVSENSE)−V(HL)<HVT), very little current passes through the transistor 124. Because very little current passes through the transistor 124, the transistor 124 remains in a nonconductive, LOW, or OFF state and the gates of the transistors 132 and 134 in the sense inverter 136 remain charged at VDD. Because the gates of the transistors 132 and 134 in the sense inverter 136 are charged at VDD, extra margin is generally provided for sensing the hit case even though the hitline signal HL is at a voltage level that is lower than the full supply voltage.

If there is a miss, when the signal HBL switches HIGH the hitline signal HL starts to be pulled down. When the difference between the voltage at the sensing node 138 and the voltage on the hitline 105 is greater than the threshold voltage of the transistor 124 (e.g., V(INVSENSE)−V(HL)>HVT), the transistor 124 starts conducting and the sensing node 138 is pulled LOW. When the voltage level of the signal INVSENSE at the sensing node 138 becomes low enough (e.g., VDD−V(INVSENSE)>VT of the transistor 132), the transistor 132 turns on, causing the signal HLN to transition HIGH, signaling a miss. At the end of the compare cycle, whether there is a hit or a miss, the signal HLDCHRG transitions HIGH to pull the hitline 105 and the sensing node 138 back to the ground potential (e.g., VSS). Discharge of the hitline 105 back to the ground potential VSS is important because if there is a hit and the hitline 105 stayed at ˜VDD/2, after multiple cycles of hits the voltage level of the hitline 105 may get charged to a higher voltage level than anticipated. The higher voltage level would take longer to sense the miss case (e.g., the falling slew rate of the hitline signal HL is very slow because of the high capacitance of the hitline 105) and the compare operation may falsely sense a hit when a miss should have been sensed.

Referring to FIG. 3, a more detailed diagram of a circuit 100′ is shown illustrating an example implementation of a hitline precharge and sensing circuit 102′ in accordance with another embodiment of the invention. The circuit 102′ may be implemented similarly to the block 102, except that a shoot through control device (e.g., a transistor 150) may be included and the signal HLN may be buffered by adding two inverters 152 and 154 after the node 140 to generate a signal (e.g., HLNB). The shoot through control device limits the dynamic power of the sensing portion of the circuit 102′. The circuit 102′ may increase noise immunity and decrease dynamic power. A sense inverter 160 of the circuit 102′ generally includes stacked PFET devices (e.g., transistors 132 and 150) to decrease shoot-through current in the sense inverter 160 during precharge. The stacked PFET devices also lower the switch point of the sense inverter 160 making the hit case more robust. The inverters 152 and 154 added after the sense inverter 160 may also lower the switch point of the sense inverter 160. The lower switch point of the sense inverter 160 provided by the addition of the two inverters 152 and 154 also increases the speed of sensing a miss.

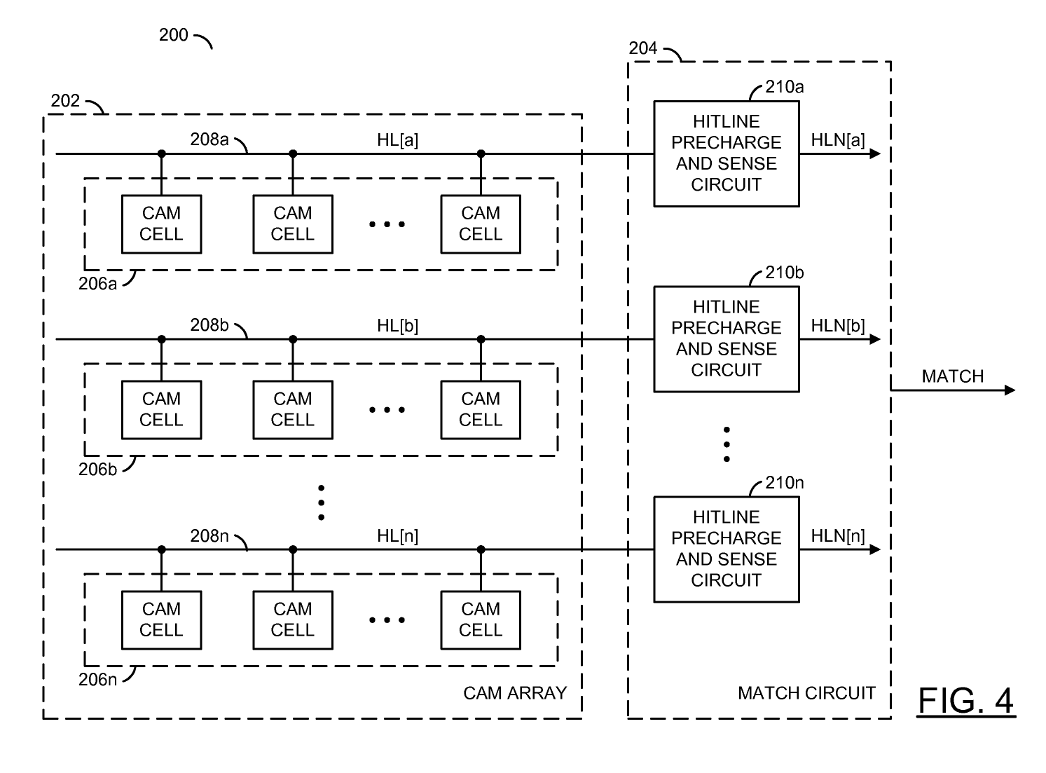

Referring to FIG. 4, a block diagram of a circuit 200 is shown illustrating a CAM memory core implemented in accordance with an embodiment of the present invention. In one example, a complete memory core may comprise a CAM array 202 and a match circuit 204.

The CAM array 202 may comprise a plurality of CAM cells arranged in a number of blocks 206a-206n and associated with a number of hitlines 208a-208n. Each of the hitlines 208a-208n generally presents a respective hitline signal (e.g., HL[a]-HL[n]). Each of the hitlines 208a-208n may be connected to a respective one of a plurality of hitline precharge and sensing circuits 210a-210n in the match circuit 204. The hitline precharge and sensing circuits 210a-210n may be implemented in some embodiments of the invention using the circuit 102 (described above in connection with FIG. 2) and in other embodiments of the invention using the circuit 102′ (described above in connection with FIG. 3). Each of the hitline precharge and sensing circuits 210a-210n may have an output that may present a respective signal (e.g., HLN[a]-HLN[n]). The signals HLN[a]-HLN[n] may be used by the circuit 204 to generate a signal (e.g., MATCH) indicating whether or not data-in bits are matched by contents of the CAM array 202.

The circuits 100 and 200 are generally illustrated implementing a local hitline. It will be apparent to those skilled in the relevant art(s) that the precharging and sensing techniques described above may be used on a global hitline as well. Low power content addressable memory (CAM) hitline precharge and sensing circuits in accordance with embodiments of the present invention may (i) reduce a precharge level of a hitline, (ii) significantly reduce dynamic power consumption, (iii) provide faster sensing of misses, (iv) provide increased operating frequency of a CAM, (v) allow a sensing node to remain at the full supply voltage while the hitline is precharged to a voltage lower than the full supply voltage, (vi) provide a shoot through control device to limit dynamic power, and/or (vi) create a sense margin using NFET devices for ensuring that hits and misses are correctly sensed.

The various signals of the present invention are generally “ON” (e.g., a digital HIGH, or 1) or “OFF” (e.g., a digital LOW, or 0). However, the particular polarities of the ON (e.g., asserted) and OFF (e.g., de-asserted) states of the signals may be adjusted (e.g., reversed) to meet the design criteria of a particular implementation. Additionally, inverters may be added to change a particular polarity of the signals. It will be apparent to those skilled in the relevant art(s) that certain nodes of transistors and other semiconductor devices may be interchanged and still achieve some desired electrical characteristics. The node interchanging may be achieved physically and/or electrically. Examples of transistor nodes that may be interchanged include, but are not limited to, the emitter and collector of bipolar transistors, the drain and source of field effect transistors, and the first base and second base of unijunction transistors.

Embodiment of the invention may also be implemented by the preparation of ASICs (application specific integrated circuits), Platform ASICs, FPGAs (field programmable gate arrays), PLDs (programmable logic devices), CPLDs (complex programmable logic device), sea-of-gates, RFICs (radio frequency integrated circuits), ASSPs (application specific standard products), one or more integrated circuits, one or more chips or die arranged as flip-chip modules and/or multi-chip modules or by interconnecting an appropriate network of conventional component circuits, as is described herein, modifications of which will be readily apparent to those skilled in the art(s).

The terms “may” and “generally” when used herein in conjunction with “is(are)” and verbs are meant to communicate the intention that the description is exemplary and believed to be broad enough to encompass both the specific examples presented in the disclosure as well as alternative examples that could be derived based on the disclosure. The terms “may” and “generally” as used herein should not be construed to necessarily imply the desirability or possibility of omitting a corresponding element.

While the invention has been particularly shown and described with reference to embodiments thereof, it will be understood by those skilled in the art that various changes in form and details may be made without departing from the scope of the invention.

1. An apparatus comprising:
a driver circuit configured to precharge a hitline in response to a predetermined voltage level and a control signal and sense a result of a compare operation based upon a hitline signal on said hitline, wherein said driver circuit precharges said hitline to a voltage level lower than said predetermined voltage level and senses said result of said compare operation using the full predetermined voltage level; and
a memory circuit configured to perform said compare operation using said hitline.

2. The apparatus according to claim 1, wherein said predetermined voltage level is selected from a supply voltage and a voltage level lower than said supply voltage.

3. The apparatus according to claim 1, wherein said memory circuit is configured as a content addressable memory (CAM) configured to operate in (i) a compare mode and (ii) a read/write mode.

4. The apparatus according to claim 1, wherein said driver circuit is coupled to said hitline by a device having a first threshold voltage when said driver circuit is precharging said hitline and a second threshold voltage when said driver circuit is sensing said hitline signal.

5. The apparatus according to claim 4, wherein said device comprises a pass gate having said first threshold voltage when a control input is in a first state and said second threshold voltage when said control input is in a second state.

6. The apparatus according to claim 5, wherein said pass gate comprises a first transistor having a first transistor threshold voltage and a second transistor having a second transistor threshold voltage, conduction paths of said first and said second transistors are connected in parallel, and said first transistor threshold voltage is lower than said second transistor threshold voltage.

7. The apparatus according to claim 1, wherein said driver circuit reduces overall dynamic power consumption of said memory during compare operations.

8. The apparatus according to claim 1, wherein said driver circuit is configured to precharge a sensing node to said predetermined voltage level and said hitline to approximately one-half of said predetermined voltage level.

9. The apparatus according to claim 1, wherein said driver circuit comprises a hitline precharge and sensing circuit.

10. The apparatus according to claim 9, wherein said apparatus comprises a plurality of said hitline precharge and sensing circuits.

11. The apparatus according to claim 10, wherein said plurality of hitline precharge and sensing circuits are selectively activated.

12. The apparatus according to claim 1, further comprising:
a control circuit configured to generate said control signal.

13. The apparatus according to claim 1, wherein said apparatus is implemented as one or more integrated circuits.

14. The apparatus according to claim 1, wherein said hitline comprises at least one of a local hitline and a global hitline.

15. An apparatus comprising:
means for precharging a hitline in response to a predetermined voltage level and a control signal and sensing a result of a compare operation based upon a hitline signal on said hitline, wherein said precharging and sensing means precharges said hitline to a voltage level lower than said predetermined voltage level and senses said result of said compare operation using the full predetermined voltage level; and
a memory circuit configured to perform said compare operation using said hitline.

16. A method for reducing power in a memory, comprising the steps of:
precharging a hitline in response to a predetermined voltage level and a control signal, wherein said hitline is precharged to a voltage level lower than said predetermined voltage level;
performing a compare operation using said hitline; and
sensing a result of said compare operation based upon a hitline signal on said hitline, wherein said result of said compare operation is sensed using the full predetermined voltage level.

17. The method according to claim 16, wherein said hitline is precharged through a device having a first threshold voltage when a control input is in a first state and a second threshold voltage when said control input is in a second state.

18. The method according to claim 17, wherein said device comprises a pass gate having said first threshold voltage when a control input is in said first state and said second threshold voltage when said control input is in said second state.

19. The method according to claim 18, wherein said pass gate comprises a first transistor having a first transistor threshold voltage and a second transistor having a second transistor threshold voltage, conduction paths of said first and said second transistors are connected in parallel, and said first transistor threshold voltage is lower than said second transistor threshold voltage.

20. The method according to claim 19, further comprising one or more of (i) selecting said first transistor from a lower voltage threshold cell library and said second transistor from a higher voltage threshold cell library, (ii) implementing said first transistor having a first length and said second transistor having a second length that is different from said first length, and (iii) implementing said first and said second transistors with different bulk voltages.
